(19) United States
(12) Patent Application Publication
(10) Pub. No.: US 2026/0357934 A1
(43) Pub. Date: Nov. 12, 2026

(54) CONNECTOR AND COOLING DEVICE

(71) Applicant: NIDEC CORPORATION, Kyoto (JP)

(72) Inventors: Genki HORIGUCHI, Kyoto (JP); Takaya OKUNO, Kyoto (JP); Takehito TAMAOKA, Kyoto (JP)

(21) Appl. No.: 19/719,792

(22) Filed: Jun. 25, 2026

Related U.S. Application Data
(63) Continuation of application No. PCT/JP2024/046119, filed on Dec. 26, 2024.

(30) Foreign Application Priority Data
Dec. 28, 2023 (JP) 2023-223067

(51) Int. Cl. F16L 23/22; F16L 23/02; F28F 3/12

(52) U.S. Cl. CPC F16L 23/22; F16L 23/02; F28F 3/12; F28F 2275/20

(57) ABSTRACT

A connector includes a first component in which a first flow path for a fluid is provided, a second component connected to the first component and in which a second flow path connected to the first flow path is provided, and a first seal and a second seal that seal between the first component and the second component. The first component includes a tubular portion extending along a first direction in which the first flow path extends. The tubular portion includes a first surface positioned outward in a radial direction of the tubular portion, and a second surface extending in a second direction intersecting the first direction. The second component includes a third surface opposed to the first surface, and a fourth surface opposed to the second surface.

### CROSS-REFERENCE TO RELATED APPLICATIONS

This application claims the benefit of International Application No. PCT/JP2024/046119, filed on Dec. 26, 2024, which claims priority to Japanese Patent Application No. 2023-223067, filed in Japan on Dec. 28, 2023, each of which is hereby incorporated herein by reference in its entirety.

### 1. FIELD OF THE INVENTION

The present disclosure relates to connectors and cooling devices.

### 2. BACKGROUND

In the related art, a connector for connecting to a known liquid port is provided with a sealing channel on an outer surface of the connector. A plurality of sealing rings are provided in the sealing channel. The plurality of sealing rings are provided side by side along a direction through which a coolant passes.

In a known connector, a plurality of sealing rings are provided side by side along a direction through which a coolant passes, whereby a sealing effect of the coolant is improved, whereas a length of the connector along the direction through which the coolant passes becomes long.

### SUMMARY

A connector according to an example embodiment of the present disclosure includes a first component, a second component, a first seal, and a second seal. A first flow path for a fluid is provided in the first component. The second component is connected to the first component, and a second flow path connected to the first flow path is provided. The first seal and the second seal are structured to seal a space between the first component and the second component. The first component includes a tubular portion extending along a first direction in which the first flow path extends. The tubular portion includes a first surface and a second surface. The first surface is positioned outward in a radial direction of the tubular portion. The second surface extends in a second direction intersecting the first direction. The second component includes a third surface and a fourth surface. The third surface is opposed to the first surface. The fourth surface is opposed to the second surface. The first seal and the second seal are annular, and are arranged on an outer circumference of the first flow path or the second flow path. The first seal is arranged between the first surface and the third surface. The second seal is arranged between the second surface and the fourth surface.

A cooling device according to an example embodiment of the present disclosure is a cooling device that cools a heat generating component. The cooling device includes a connector and a cold plate. The cold plate is thermally contactable with the heat generating component. The second component includes a cover that covers the cold plate. The first component includes a joint attachable to and detachable from the cover.

The above and other elements, features, steps, characteristics and advantages of the present disclosure will become more apparent from the following detailed description of example embodiments with reference to the attached drawings.

### BRIEF DESCRIPTION OF THE DRAWINGS

FIG. 1 is a perspective view showing a cooling device according to an example embodiment of the present disclosure.

FIG. 2 is an exploded view of the cooling device according to an example embodiment of the present disclosure.

FIG. 3 is a sectional view of the cooling device taken along line III-III shown in FIG. 2.

FIG. 4 is a sectional view of the cooling device taken along line IV-IV shown in FIG. 1.

FIG. 5 is a schematic view showing a connector according to an example embodiment.

FIG. 6 is a schematic view showing a connector according to an example embodiment.

FIG. 7 is a schematic view showing a connector according to an example embodiment.

FIG. 8 is a schematic view showing a connector according to an example embodiment.

### DETAILED DESCRIPTION

Example embodiments of the present disclosure will be described below with reference to the drawings.

Note that in the drawings, identical or corresponding portions are given identical reference signs, and the description will not be repeated. In the present description, a first direction Z, a second direction X, and a third direction Y orthogonal to one another are appropriately described for easy understanding. One side in the first direction Z is described as a one side Z1 in the first direction, and the other side in the first direction Z is described as an other side Z2 in the first direction. One side in the second direction X is described as a one side X1 in the second direction, and the other side in the second direction X is described as an other side X2 in the second direction. One side in the third direction Y is described as a one side Y1 in the third direction, and the other side in the third direction Y is described as an other side Y2 in the third direction. However, the directions are defined merely for convenience of description, and the orientations at the time of use of the example connector and the cooling device of the present disclosure are not limited unless it is necessary to define a horizontal direction and a vertical direction in particular. In the present description, an “orthogonal direction” includes a substantially orthogonal direction.

It is noted that numerical values, ratios, ranges, quantitative relationships, and positional relationships such as parallel, perpendicular, etc., described or recited herein are merely non-limiting examples unless otherwise expressly stated in the description or claims, and include within the scope thereof inherent imprecision associated with manufacturing tolerances, measurement tolerances, and the practical limitations of the instruments and techniques used to determine such values, ratios, ranges, quantitative relationships, and positional relationships, as would be understood by a person of ordinary skill in the relevant art, and further encompass a variation that is reasonable and customary in the relevant art or field of technology for the type of measurement or parameter at issue.

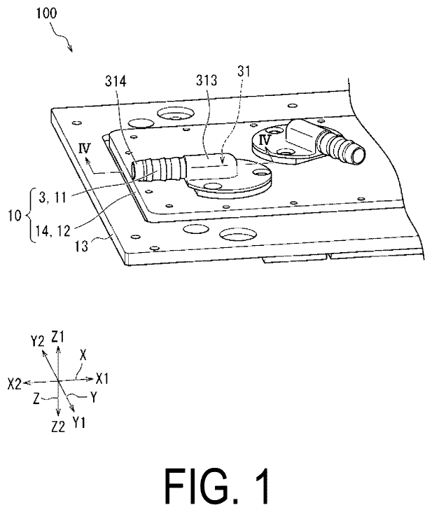

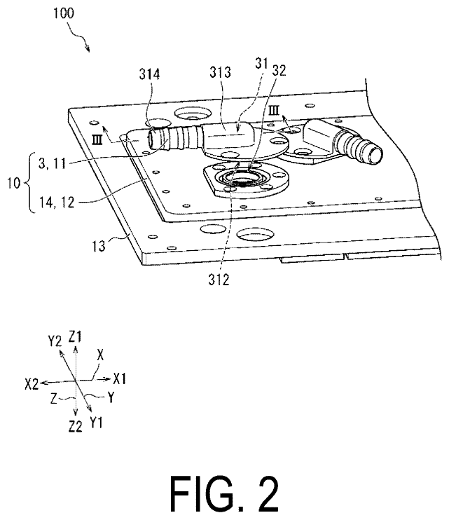

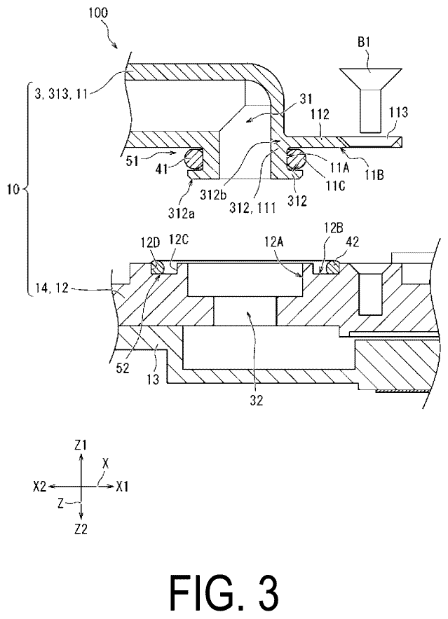

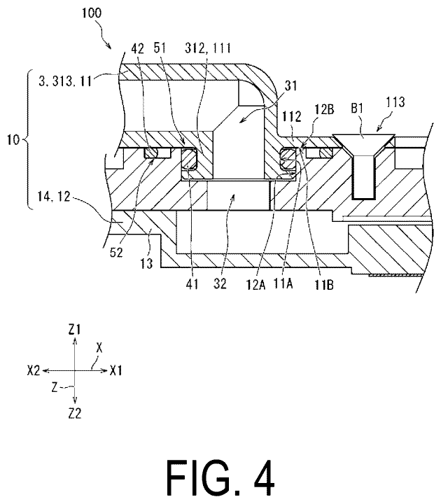

A cooling device 100 including a connector 10 according to an example embodiment will be described with reference to FIGS. 1 to 4. FIG. 1 is a perspective view showing the cooling device 100 according to an example embodiment. FIG. 2 is an exploded view of the cooling device 100. FIG. 3 is a sectional view of the cooling device 100 taken along line III-III shown in FIG. 2. FIG. 4 is a sectional view of the cooling device 100 taken along line IV-IV shown in FIG. 1.

The cooling device 100 includes a cold plate 13 and the connector 10. The cold plate 13 is thermally contactable with a heat generating component not shown. The cooling device 100 passes refrigerant through the inside of the cooling device 100 and causes heat exchange between the heat generating component not shown and the refrigerant via the cold plate 13 to cool the heat generating component. The cold plate 13 has a substantially rectangular parallelepiped outer shape that is thin in the first direction Z. The heat generating component not shown is positioned on the other side Z2 in the first direction of the cold plate 13 and is thermally contactable with a surface on the other side Z2 in the first direction of the cold plate 13. The cold plate 13 is manufactured from a high thermal conductivity material. Examples of this type of material include metals such as copper and aluminum. In addition, the cold plate 13 can be manufactured from fine ceramics containing aluminum nitride or silicon carbide. The refrigerant is liquid or gas, and is an example of the fluid.

The connector 10 connects the cold plate 13 and an external component other than the cold plate 13. The connector 10 includes a cover 14 and one or more joints 3. The cover 14 covers the cold plate 13. Specifically, the cover 14 covers a surface of the cold plate 13 on the one side Z1 in the first direction. A flow path not shown through which the refrigerant passes is provided between the cold plate 13 and the cover 14. A flow path 32 connected to the flow path not shown provided between the cold plate 13 and the cover 14 is provided in the cover 14. The flow path 32 is provided as a through-hole penetrating the cover 14 in the first direction Z.

The joint 3 is attachable to and detachable from the cover 14. Specifically, a portion of the joint 3 is positioned inside the through-hole of the cover 14. In an example embodiment, the number of the joints 3 is two. Each of the joints 3 is a pipe joint having a specification identical to one another. However, the present disclosure is not limited to this, and the number of the joints 3 may be one or three or more, and the joints 3 may be pipe joints having specifications different from one another.

A flow path 31 connected to the flow path 32 is provided in the joint 3. Specifically, each of the joints 3 includes the flow path 31, an insertion port 312, a main body 313, and an insertion port 314. The insertion port 312 is positioned inside the through-hole of the cover 14. The insertion port 312 has a tubular shape. The insertion port 312 extends in the first direction Z in a state of being positioned inside the through-hole of the cover 14. An outer circumferential surface of the insertion port 312 has a substantially columnar shape.

In the main body 313, the flow path 31 is provided inside the main body 313. The main body 313 connects the insertion port 312 and the insertion port 314. One end of the main body 313 is provided with the insertion port 312. The insertion port 314 is provided at the other end of the main body 313 on the opposite side to the side provided with the insertion port 312. An external component is connected to the insertion port 314. The external component is, for example, a pipe through which the refrigerant passes.

The flow path 31 reaches a tip end of the insertion port 314 through the insertion port 312, the main body 313, and the insertion port 314 from an end portion 312a on the other side Z2 in the first direction of the insertion port 312. In an example embodiment, the main body 313 and the insertion port 314 extend in a direction different from that of the insertion port 312. However, the present disclosure is not limited to this, and the main body 313 and the insertion port 314 may extend in the same direction (first direction Z) as that of the insertion port 312.

As described above, the connector 10 connects the first component 11 in which the flow path 31 is provided and the second component 12 in which the flow path 32 is provided. That is, the first component includes the joint 3. The second component 12 includes the cover 14. When the first component 11 and the second component 12 are connected, the flow path 32 is connected to the flow path 31. The flow path 31 is an example of the first flow path. The flow path 32 is an example of the second flow path.

In an example embodiment, the first component 11 includes a tubular portion 111 extending along the first direction Z in which the flow path 31 extends. In the cooling device 100, the insertion port 312 provides the tubular portion 111.

The tubular portion 111 includes a first surface 11A positioned outward in the radial direction of the tubular portion 111. In the cooling device 100, the first surface 11A is an outer circumferential surface of the insertion port 312.

The tubular portion 111 includes a flange portion 112 extending outward in the radial direction from the first surface 11A. The flange portion 112 extends outward in the radial direction from a position apart toward the one side Z1 in the first direction from an end portion on the opposite side to the side on which the cover 14 is positioned in the first direction Z of the tubular portion 111. That is, the flange portion 112 is arranged apart toward the one side Z1 in the first direction relative to the end portion 312a on the other side Z2 in the first direction of the tubular portion 111 (the insertion port 312). Typically, the flange portion 112 is provided at an end portion 312b on the one side Z1 in the first direction of the tubular portion 111 (the insertion port 312). The flange portion 112 has a plate shape that is thin in the first direction Z, and extends in a circumferential direction of the tubular portion 111 (the insertion port 312). The flange portion 112 has a substantially circular shape in plan view from the first direction Z.

Furthermore, the first component 11 includes a second surface 11B extending in the second direction X and the third direction Y. The second surface 11B extends outward in the radial direction from an end portion of the first surface 11A of the tubular portion 111 on the side opposite to the side on which the second component 12 (the cover 14) is positioned in the first direction Z. Specifically, the second surface 11B extends outward in the radial direction from the end portion 312b on the one side Z1 in the first direction of the tubular portion 111 (the insertion port 312). In an example embodiment, the second surface 11B is provided on the side of the flange portion 112 on which the second component 12 (the cover 14) is positioned in the first direction Z.

On the other hand, the second component 12 includes a third surface 12A and a fourth surface 12B. The third surface 12A is opposed to the outer circumferential surface of the insertion port 312, which is the first surface 11A of the first component 11. Specifically, the third surface 12A is provided in a portion of the one side Z1 in the first direction of the through-hole in which the flow path 32 is provided in the second component 12 (the cover 14). The fourth surface 12B is opposed to the second surface 11B of the first component 11. In an example embodiment, the fourth surface 12B is a surface of the second component 12 (the cover 14) facing the one side Z1 in the first direction.

In an example embodiment, the connector 10 (the cooling device 100) includes two O-rings 41 and 42 that seal between the first component 11 (the joint 3) and the second component 12 (the cover 14). Each of the O-ring 41 and the O-ring 42 is an annular element and is arranged on the outer circumference of the flow path 31 or the flow path 32. The O-ring 41 is an example of the first seal. The O-ring 42 is an example of the second seal.

The O-ring 41 is arranged between the first surface 11A of the first component 11 (the joint 3) and the third surface 12A of the second component 12 (the cover 14). In a state in which the insertion port 312 of the joint 3 is positioned inside the through-hole of the cover 14, the O-ring 41 comes into contact with the first surface 11A and the third surface 12A and seals between the first surface 11A and the third surface 12A. The O-ring 42 is arranged between the second surface 11B of the first component 11 (the joint 3) and the fourth surface 12B of the second component 12 (the cover 14). In the state in which the insertion port 312 of the joint 3 is positioned inside the through-hole of the cover 14, the O-ring 42 comes into contact with the second surface 11B and the fourth surface 12B and seals between the second surface 11B and the fourth surface 12B.

In this manner, in an example embodiment, the O-ring 41 and the O-ring 42 can be arranged at positions apart from each other in the radial direction of the tubular portion 111 and the same position in the first direction Z. Hence, between the first component 11 (the joint 3) and the second component 12 (the cover 14), a gap provided along the first direction Z is sealed by the O-ring 41, and a gap provided along the second direction X and the third direction Y is sealed by the O-ring 42. As a result, as compared with a case in which the O-rings are arranged side by side along the first direction Z, the length along the first direction Z of the connector 10 can be shortened while doubly sealing between the first component 11 (the joint 3) and the second component 12 (the cover 14).

For example, the O-ring 41 is accommodated in a first accommodation space 51. The first accommodation space 51 is provided by at least the first surface 11A and the third surface 12A. In an example embodiment, the first accommodation space 51 is provided in the first component 11 (the joint 3). Specifically, the first accommodation space 51 is provided by the first surface 11A, which is the outer circumferential surface of the tubular portion 111 (the insertion port 312), the second surface 11B provided in the flange portion 112, and a surface 11C on the one side Z1 in the first direction of a flange 312f extending outward in the radial direction of the tubular portion 111 (the insertion port 312) from the end portion 312a on the other side Z2 in the first direction of the first component 11 (the joint 3), and is provided as a groove extending along the outer circumferential surface of the tubular portion 111 (the insertion port 312). Specifically, the first accommodation space 51 is provided by the second surface 11B and the surface 11C, which are side wall portions of the groove, in addition to the first surface 11A, which is the bottom of the groove. The O-ring 41 is arranged in the groove provided by the first surface 11A, the second surface 11B, and the surface 11C. Furthermore, in the state in which the insertion port 312 of the joint 3 is positioned inside the through-hole of the cover 14, the third surface 12A covers the side opposite to the first surface 11A side of the O-ring 41, and the first accommodation space 51 is provided.

The O-ring 42 is accommodated in a second accommodation space 52. The second accommodation space 52 is provided by at least the second surface 11B and the fourth surface 12B. In an example embodiment, the second accommodation space 52 is provided in the second component 12 (the cover 14). Specifically, the second accommodation space 52 is provided as an annular groove recessed on the other side Z2 in the first direction from a surface of the cover 14 facing the one side Z1 in the first direction. Specifically, the second accommodation space 52 is provided by side wall surfaces 12C and 12D, which are side wall portions of the groove, in addition to the fourth surface 12B, which is the bottom of the groove. The side wall surface 12C is positioned inward in the radial direction of the tubular portion 111 relative to the fourth surface 12B. The side wall surface 12D is positioned outward in the radial direction of the tubular portion 111 relative to the fourth surface 12B. The O-ring 42 is arranged in the groove provided by the fourth surface 12B, the side wall surface 12C, and the side wall surface 12D. Furthermore, in the state in which the insertion port 312 of the joint 3 is positioned inside the through-hole of the cover 14, the second surface 11B covers the side opposite to the fourth surface 12B side of the O-ring 42, and the second accommodation space 52 is provided.

In an example embodiment, the second surface 11B providing the first accommodation space 51 and the second surface 11B providing the second accommodation space 52 are at the same position in the first direction Z. Therefore, it becomes possible to provide the first accommodation space 51 and the second accommodation space 52 without providing a recess portion or a protrusion portion having a distance along the first direction Z on the second surface 11B. As a result, the shape of the first component 11 (the joint 3) including the second surface 11B becomes simplified, and the first component 11 (the joint 3) can be easily manufactured.

For example, the thickness of the O-ring 41 is different from the thickness of the O-ring 42. In an example embodiment, by selecting the thicknesses of the O-ring 41 and the O-ring 42 in accordance with the diameter of the tubular portion 111 or the length in the first direction Z, it becomes possible to compactly provide the connector 10 while maintaining the sealing effect by the O-ring 41 and the O-ring 42. In particular, in a case in which the thickness of the O-ring 42 is thinner than the thickness of the O-ring 41, the length along the radial direction of the first component 11 (the joint 3) can be shortened.

In an example embodiment, the flange portion 112 is fastened and fixed to the second component 12 (the cover 14) by a fastener B1 such as a screw.

Specifically, the flange portion 112 includes a fastened portion 113 to be fastened to the fourth surface 12B of the second component 12 (the cover 14). The fastened portion 113 is a through-hole penetrating the flange portion 112 in the first direction Z. A portion of the fastener B1 is positioned in the fastened portion 113. For example, the sectional area of the fastened portion 113 on the one side Z1 in the first direction is larger than the sectional area of the fastened portion 113 on the other side Z2 in the first direction. The sectional area of the fastened portion 113 on the other side Z2 in the first direction has a size that allows a screw portion of the fastener B1 to pass therethrough and does not allow a head portion of the fastener B1 to pass therethrough.

By this, the first component 11 (the joint 3) is fastened and fixed to the second component 12 (the cover 14). Therefore, another element for fixing the first component 11 (the joint 3) to the second component 12 (the cover 14) becomes unnecessary. Hence, the number of components required for connection between the first component 11 (the joint 3) and the second component 12 (the cover 14) can be reduced.

Next, a connector according to another example embodiment will be described. This example embodiment is different from the previous example embodiment in a connection target by the connector. Hereinafter, matters different from the previous example embodiment will be described, and description of matters overlapping with the previous example embodiment will be omitted.

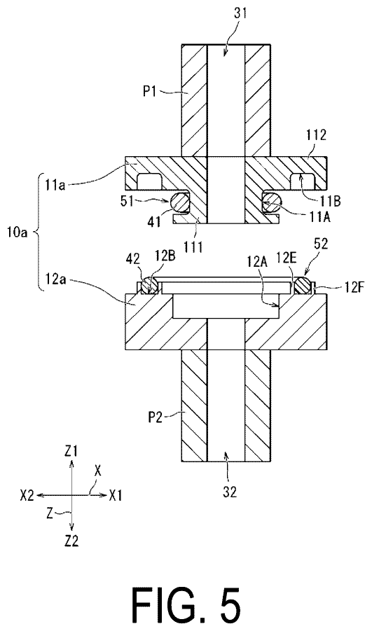

A connector 10a according to an example embodiment will be described with reference to FIG. 5. FIG. 5 is a schematic view showing the connector 10a according to an example embodiment.

For example, the connector 10a is used for connection between a pipe P1 in which the flow path 31 is provided and a pipe P2 in which the flow path 32 is provided. The pipe P1 includes a first component 11a. The first component 11a is provided at an end portion of the pipe P1 on the other side Z2 in the first direction. The pipe P2 includes a second component 12a. The second component 12a is provided at an end portion of the pipe P2 on the one side Z1 in the first direction. The first component 11a is the same as the first component 11 of the previous example embodiment except that the fastened portion 113 is not provided and the shape of the second surface 11B is different. The second component 12a is the same as the second component 12 except that the shape of the second accommodation space 52 is different.

Specifically, the second component 12a includes two projection portions 12E and 12F extending from the fourth surface 12B to the one side Z1 in the first direction. Each of the projection portion 12E and the projection portion 12F is annular and is arranged on the outer circumference of the flow path 31 or the flow path 32. The projection portion 12E and the projection portion 12F are arranged side by side in the radial direction of the tubular portion 111. Specifically, the projection portion 12F is positioned outward relative to the projection portion 12E in the radial direction of the tubular portion 111. The O-ring 42 is arranged between the projection portion 12E and the projection portion 12F. That is, the second accommodation space 52 is provided between the projection portion 12E and the projection portion 12F. On the other hand, an annular groove corresponding to the projection portion 12E and the projection portion 12F is provided on a surface of the first component 11a opposed to the fourth surface 12B of the second component 12a. The groove provided on the second surface 11B of the first component 11a is recessed to the one side Z1 in the first direction. The width of the groove provided on the second surface 11B of the first component 11a is substantially the same as the length along the radial direction of the tubular portion 111 from the projection portion 12E to the projection portion 12F. The depth of the groove provided on the second surface 11B of the first component 11a is substantially the same as the lengths along the first direction Z of the projection portion 12E and the projection portion 12F.

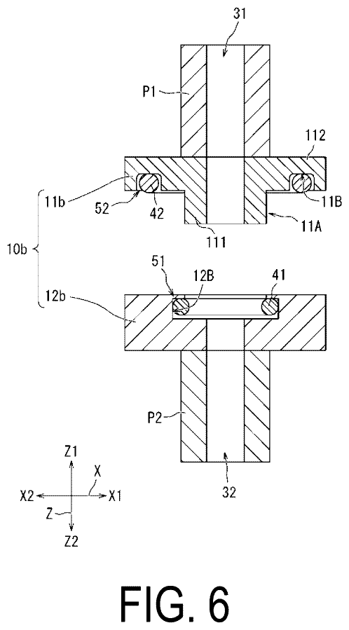

Next, a connector 10b according to an example embodiment will be described with reference to FIG. 6. FIG. 6 is a schematic view showing the connector 10b according to an example embodiment.

The connector 10b is different from the connector 10a in the shapes of the first accommodation space 51 and the second accommodation space 52. Specifically, the connector 10b includes a first component 11b and a second component 12b. In the connector 10b, the first accommodation space 51 is provided in the second component 12b. The second accommodation space 52 is provided in the first component 11b. That is, in the connector 10b, the first accommodation space 51 is provided as an annular groove recessed outward in the radial direction of the tubular portion 111 on a surface of the second component 12b opposed to the first surface 11A of the first component 11b. On the other hand, in the connector 10b, the first accommodation space 51 is provided as an annular groove recessed to the other side Z2 in the first direction on a surface of the first component 11b opposed to the fourth surface 12B of the second component 12b.

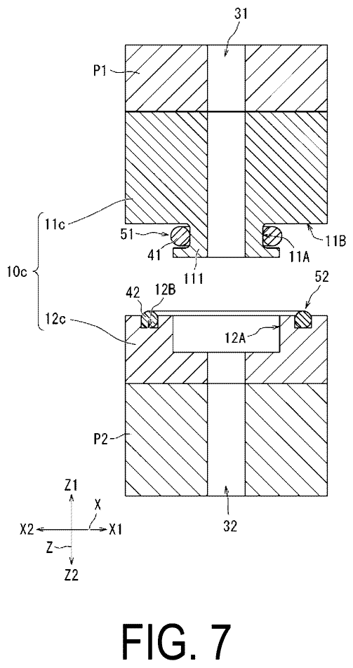

Next, a connector 10c according to an example embodiment will be described with reference to FIG. 7. FIG. 7 is a schematic view showing the connector 10c according to an example embodiment. The connector 10c is different from the connector 10a in the shape of the first component and the shape of the second component. Specifically, the connector 10c includes a first component 11c and a second component 12c. The second component 12c is provided with the second accommodation space 52. The second accommodation space 52 is provided as an annular groove recessed on the other side Z2 in the first direction from a surface of the second component 12c facing the one side Z1 in the first direction of the first component 11c.

On the other hand, the first component 11c includes the second surface 11B without being provided with the flange portion 112. In the first component 11c, the second surface 11B is a surface extending outward in the radial direction of the tubular portion 111 from the first surface 11A of the tubular portion 111 and facing the other side Z2 in the first direction. In this manner, when the second surface 11B is provided outward in the radial direction of the tubular portion 111, an area where the first component 11c and the second component 12c are in contact with each other increases, and it becomes difficult for a fluid to pass between the first component 11c and the second component 12c. As a result, the fluid sealing effect between the first component 11c and the second component 12c further increases.

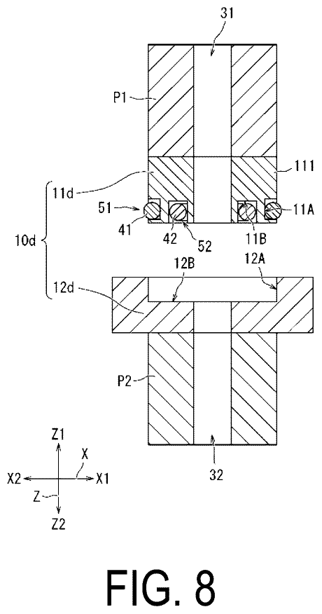

Next, a connector 10d according to an example embodiment will be described with reference to FIG. 8. FIG. 8 is a schematic view showing the connector 10d according to an example embodiment. The connector 10d includes a first component 11d and a second component 12d. The first component 11d includes the first surface 11A and the second surface 11B. The second surface 11B of the first component 11d is a surface extending inward in the radial direction of the tubular portion 111 from an end portion on the other side Z2 in the first direction of the tubular portion 111 and facing the other side Z2 in the first direction. The first accommodation space 51 is provided on the first surface 11A of the first component 11d. The second accommodation space 52 is provided on the second surface 11B of the first component 11d. Hence, in the connector 10d, the O-ring 42 is positioned inward relative to the O-ring 41 in the radial direction of the tubular portion 111.

Also in this case, between the first component 11d and the second component 12d, a gap provided along the first direction Z is sealed by the O-ring 41, and a gap provided along the second direction X and the third direction Y is sealed by the O-ring 42. As described above, the connector 10d according to an example embodiment includes the first component 11d in which the flow path 31 is provided, the second component 12d in which the flow path 32 is provided, and the O-ring 41 and the O-ring 42 that seal between the first component 11d and the second component 12d. The first component 11d includes the tubular portion 111 extending along the first direction Z. The tubular portion 111 includes the first surface 11A and the second surface 11B. The second component 12d includes the third surface 12A and the fourth surface 12B. The O-ring 41 is arranged between the first surface 11A and the third surface 12A. The O-ring 42 is arranged between the second surface 11B and the fourth surface 12B. Therefore, as compared with a case in which the O-rings are arranged side by side along the first direction Z, the length along the first direction Z of the connector 10 can be shortened while doubly sealing between the first component 11d and the second component 12d.

The embodiments of the present disclosure have been described above with reference to the drawings. However, the present disclosure is not limited to the embodiments described above, and can be carried out in various aspects without departing from the gist thereof. The plurality of elements disclosed in the embodiments described above can be appropriately modified. For example, a certain element of all elements shown in a certain embodiment may be added to an element of another embodiment, or some elements of all elements shown in a certain embodiment may be deleted from the embodiment.

The drawings schematically show mainly each element in order to facilitate understanding of the present disclosure, and the thickness, length, number, interval, and the like of each element that is shown may be different from the actual ones for convenience of creation of the drawings. The configuration of each element shown in the embodiments described above is an example and is not particularly limited, and it goes without saying that various modifications can be made without substantially departing from the effects of the present disclosure.

Note that the present technology can include the following configurations.
(1) A connector including a first component in which a first flow path for a fluid is provided, a second component connected to the first component, the second component in which a second flow path connected to the first flow path is provided, and a first seal and a second seal that seal between the first component and the second component. The first component includes a tubular portion extending along a first direction in which the first flow path extends. The tubular portion includes a first surface positioned outward in a radial direction of the tubular portion, and a second surface extending in a second direction intersecting the first direction. The second component includes a third surface opposed to the first surface, and a fourth surface opposed to the second surface. The first seal and the second seal are annular, and are arranged on an outer circumference of the first flow path or the second flow path. The first seal is arranged between the first surface and the third surface. The second seal is arranged between the second surface and the fourth surface.
(2) The connector according to (1), in which the second surface extends outward in the radial direction from an end portion of the first surface on a side opposite to a side on which the second component is positioned in the first direction.
(3) The connector according to (1) or (2), in which the tubular portion includes a flange portion extending outward in the radial direction from the first surface, the second surface is provided on a side of the flange portion on which the second component is positioned in the first direction, and the flange portion includes a fastened portion to be fastened to the fourth surface.
(4) The connector according to any of (1) to (3), in which a first accommodation space that accommodates the first seal is provided by at least the first surface, the second surface, and the third surface, a second accommodation space that accommodates the first seal is provided by at least the second surface and the fourth surface, and the second surface providing the first accommodation space and the second surface providing the second accommodation space are at a same position in the first direction.
(5) The connector according to any of (1) to (4), in which a thickness of the first seal is different from a thickness of the second seal.
(6) A cooling device that cools a heat generating component, the cooling device including the connector according to any one of (1) to (5), and a cold plate thermally contactable with the heat generating component. The second component includes a cover that covers the cold plate, and the first component includes a joint attachable to and detachable from the cover.

Example embodiments of the present disclosure is applicable to the field of connectors.

Features of the above-described example embodiments and the modifications thereof may be combined appropriately as long as no conflict arises.

A number of implementations have been described. Nevertheless, it will be understood that various modifications may be made without departing from the spirit and scope of the disclosure. Further, it should be understood that the foregoing description is only illustrative of the present disclosure. Various alternatives and modifications can be devised by those skilled in the art without departing from the present disclosure. Accordingly, the present disclosure is intended to embrace all such alternatives, modifications, and variances that fall within the scope of the appended claims.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A connector comprising:
a first component in which a first flow path for a fluid is provided;
a second component connected to the first component, the second component in which a second flow path connected to the first flow path is provided;
a first seal and a second seal that seal between the first component and the second component,
the first component including a tubular portion extending along a first direction in which the first flow path extends,
the tubular portion including a first surface positioned outward in a radial direction of the tubular portion, and a second surface extending in a second direction intersecting the first direction,
the second component including a third surface opposed to the first surface, and a fourth surface opposed to the second surface,
the first seal and the second seal being annular, and being arranged on an outer circumference of the first flow path or the second flow path,
the first seal being arranged between the first surface and the third surface, and
the second seal being arranged between the second surface and the fourth surface.

2. The connector according to claim 1, wherein the second surface extends outward in the radial direction from an end portion of the first surface on a side opposite to a side on which the second component is positioned in the first direction.

3. The connector according to claim 2, wherein
the tubular portion includes a flange portion extending outward in the radial direction from the first surface, the second surface is provided on a side of the flange portion on which the second component is positioned in the first direction, and
the flange portion includes a fastened portion to be fastened to the fourth surface.

4. The connector according to claim 2, wherein a first accommodation space that accommodates the first seal is provided by at least the first surface, the second surface, and the third surface, a second accommodation space that accommodates the second seal is provided by at least the second surface and the fourth surface, and the second surface providing the first accommodation space and the second surface providing the second accommodation space are at a same position in the first direction.

5. The connector according to claim 1, wherein a thickness of the first seal is different from a thickness of the second seal.

6. A cooling device that cools a heat generating component, the cooling device comprising:
the connector according to claim 1; and
a cold plate thermally contactable with the heat generating component,
the second component including a cover that covers the cold plate, and
the first component including a joint attachable to and detachable from the cover.
